(19) United States
(12) Patent Application Publication
(10) Pub. No.: US 2026/0186219 A1
(43) Pub. Date: Jul. 2, 2026

(54) Intertwined TROSA Heatsink Fin Adapter for High Power TROSA Heatsink for Bidirectional Coherent Optics for Outdoor Conduction Cooled System

(71) Applicant: Ciena Corporation, Hanover, MD (US)

(72) Inventors: Rampratap Mahawar, Gurugram (IN); Shubham Kumar, Gurugram (IN); Chander Prakash Gupta, Gurugram (IN); Prem Singh, Distt-Etah (IN)

(21) Appl. No.: 19/047,707

(22) Filed: Feb. 7, 2025

(30) Foreign Application Priority Data
Dec. 26, 2024 (IN) 202411103328

(51) Int. Cl. G02B 6/42; H05K 7/20

(52) U.S. Cl. CPC G02B 6/4269; H05K 7/20418

(57) ABSTRACT

A transmit-receive optical sub-assembly (TROSA) fin adapter assembly that effectively thermally couples the heatsink fins and plug body of a plug with a cold plate or chassis heatsink. The TROSA fin adapter assembly includes an adapter body that is disposed above and around the heatsink fins of the plug and a plurality of adapter fins that are disposed between and intertwined with the heatsink fins of the plug. Optionally, the TROSA fin adapter assembly includes adapter sides that are also disposed adjacent to the sides of the plug body. Thus, the TROSA fin adapter provides a conformal thermal interface between the heatsink fins and plug body of the plug and the cold plate or chassis heatsink. The result is the TROSA of the high power optics of the BiDi coherent plug of an air cooled conduction system, such as an outdoor system, being adequately cooled under most ambient conditions.

### CROSS-REFERENCE TO RELATED APPLICATION

The present disclosure claims the benefit of priority of co-pending Indian Patent Application No. 202411103328, filed on Dec. 26, 2024, the contents of which are incorporated in full by reference.

### TECHNICAL FIELD

The present disclosure relates generally to the telecommunications and networking fields. More particularly, the present disclosure relates to an intertwined transmit-receive optical sub-assembly (TROSA) heatsink fin adapter for a high power TROSA heatsink for bidirectional (BiDi) coherent optics for an outdoor conduction cooled system.

### BACKGROUND

Various solutions exist to cool the TROSAs of high power coherent plugs that consume less than 3-5 W of power, with the back side electronics consuming the rest of the power (>15 W). However, some plugs have additional thermal distribution requirements, such as BiDi coherent plugs with 20 W optics. Out of the 20 W, almost 10 W can be consumed by the TROSA portion of the plug that extends from the faceplate or wall of the associated module, with the remaining 10 W being consumed by the rest of the optics. For such QSFP-DD plugs and the like, the heatsink associated with the TROSA may have fins with extended heights for adequate cooling in an air cooled conduction system, such as an outdoor system.

FIG. 1 shows such a typical TROSA conduction cooling heatsink assembly 100. As shown, the plug 102, which may be a QSFP-DD or the like, includes a plurality of heatsink fins 104 that are coupled to or integrally formed with and extend from the plug body 102a of the plug 102. These heatsink fins 104 are normally associated with convection cooling, but are surrounded by a cold plate or chassis heatsink 106 that surrounds the plug body 102a and heatsink fins 104 of the plug 102, serving to conduct heat away from the plug body 102a and heatsink fins 104. Optionally, the cold plate or chassis heatsink 106 may be liquid cooled, but in any case provides an increased surface area for heat conduction. The cold plate or heatsink chassis 106 is thermally coupled to the plug body 102a and heatsink fins 104 via one or more thermal gaskets 108 disposed between the cold plate or chassis heatsink 106 and the plug body 102a and heatsink fins 104. These thermal gaskets 108 may each be manufactured from a compliant thermal transmission material, include a thermally transmissive graphite-over-foam (GoF) pad, or the like. As shown, disadvantageously, the thermal gasket 108 disposed at the top of the heatsink fins 104 contacts only the tips of the heatsink fins 104, limiting thermal conduction between the heatsink fins 104 and the cold plate or chassis heatsink 106. It should be noted that this same problem is present if the cold plate or chassis heatsink 106 directly contacts the plug body 102a and heatsink fins 104, without the use of the intervening thermal gaskets 108. It should also be noted that the cold plate or heatsink chassis 106 includes a top heatsink portion 106a disposed along the top of the heatsink fins 104 and side heatsink portions 106b that extend downwards along the sides of the heatsink fins 104 and the plug body 102a. The spacing of the heatsink fins 104, which are typically manufactured from aluminum or the like, is on the order to 0.8-1 mm, for example.

The limited contact between the heatsink fins 104 and thermal gasket 108 or cold plate or chassis heatsink 106 of this arrangement limits thermal conduction, which is problematic for the TROSA 110 of the high power optics of the BiDi coherent plug 102 of an air cooled conduction system, such as an outdoor system. In such applications, the TROSA 110, which extends from the faceplate or wall 112 of the associated module 114 of the system 116, may consume 10 W, for example, generating excessive heat. Further, the height of the heatsink fins 104 may vary between plugs 102, requiring the arrangement to be varied between plugs types for adequate thermal conduction. The result is conduction cooled systems with total plug powers of ˜19 W and plug section powers of ˜1.5-11 W being inadequately cooled in some cases and/or under some ambient conditions.

The present background is provided as environmental context only. It will be readily apparent to those of ordinary skill in the art that the principles and concepts of the present disclosure may be implemented in other environmental contexts equally, without limitation.

### SUMMARY

The present disclosure provides a TROSA heatsink fin adapter assembly that replaces at least the top thermal gasket of the above arrangement, and optionally all of the thermal gaskets of the above arrangement, to more effectively thermally couple the heatsink fins and plug body of the plug with the cold plate or chassis heatsink. The TROSA heatsink fin adapter assembly includes an adapter body that is disposed above and around the heatsink fins of the plug and a plurality of adapter fins that are disposed between and intertwined with the heatsink fins of the plug. Optionally, the TROSA heatsink fin adapter assembly includes adapter sides that are also disposed adjacent to the sides of the plug body. Thus, the TROSA heatsink fin adapter provides a conformal thermal interface between the heatsink fins and plug body of the plug and the cold plate or chassis heatsink. The result is the TROSA of the high power optics of the BiDi coherent plug of an air cooled conduction system, such as an outdoor system, being adequately cooled, even with total plug powers of ˜19 W and plug section powers of ˜1.5-11 W, for example, under most ambient conditions.

In some embodiments, the present disclosure provides a heatsink fin adapter assembly including an adapter body adapted to be disposed above a plurality of heatsink fins of a plug, adapter side walls adapted to be disposed around the plurality of heatsink fins of the plug, and a plurality of adapter fins extending from the adapter body between the adapter side walls adapted to be disposed between and intertwined with the plurality of heatsink fins of the plug, where the adapter body, the adapter side walls, and the plurality of adapter fins are adapted to conduct heat from the plurality of heatsink fins and a plug body of the plug. In some embodiments, the adapter body is adapted to be disposed adjacent to tips of the plurality of heatsink fins of the plug. In some embodiments, the adapter body is adapted to be spaced apart from tips of the plurality of heatsink fins of the plug. The adapter body is adapted to be disposed adjacent to a top heatsink portion of a cold plate or chassis heatsink disposed about the heatsink fin adapter assembly. In some embodiments, the adapter side walls are elongated such that the adapter side walls are adapted to be disposed adjacent to sides of the plug body of the plug. The adapter side walls are adapted to be disposed adjacent to heatsink side portions of a cold plate or chassis heatsink disposed about the heatsink fin adapter assembly. In some embodiments, the adapter side walls are adapted to be disposed adjacent to the heatsink side portions of the cold plate or chassis heatsink disposed about the heatsink fin adapter assembly through intervening thermal gaskets. In some embodiments, surfaces of one or more of the adapter body, the adapter side walls, and the plurality of adapter fins are coated with a thermal interface material. The plurality of heatsink fins are disposed adjacent to a transmit-receive optical sub-assembly section of the plug body of the plug. In some embodiments, the plug is a bidirectional coherent optics plug.

In some embodiments, the present disclosure provides a transmit-receive optical sub-assembly conduction cooling heatsink assembly including a heatsink fin adapter assembly including an adapter body adapted to be disposed above a plurality of heatsink fins of a plug, adapter side walls adapted to be disposed around the plurality of heatsink fins of the plug, and a plurality of adapter fins extending from the adapter body between the adapter side walls adapted to be disposed between and intertwined with the plurality of heatsink fins of the plug, and a cold plate or chassis heatsink disposed about the heatsink fin adapter assembly, where the adapter body, the adapter side walls, and the plurality of adapter fins of the heatsink fin adapter assembly are adapted to conduct heat from the plurality of heatsink fins and a plug body of the plug to the cold plate or chassis heatsink. In some embodiments, the adapter body is adapted to be disposed adjacent to tips of the plurality of heatsink fins of the plug. In some embodiments, the adapter body is adapted to be spaced apart from tips of the plurality of heatsink fins of the plug. The adapter body is adapted to be disposed adjacent to a top heatsink portion of the cold plate or chassis heatsink disposed about the heatsink fin adapter assembly. In some embodiments, the adapter side walls are elongated such that the adapter side walls are adapted to be disposed adjacent to sides of the plug body of the plug. The adapter side walls are adapted to be disposed adjacent to heatsink side portions of the cold plate or chassis heatsink disposed about the heatsink fin adapter assembly. In some embodiments, the adapter side walls are adapted to be disposed adjacent to the heatsink side portions of the cold plate or chassis heatsink disposed about the heatsink fin adapter assembly through intervening thermal gaskets. In some embodiments, surfaces of one or more of the adapter body, the adapter side walls, and the plurality of adapter fins are coated with a thermal interface material. The plurality of heatsink fins are disposed adjacent to a transmit-receive optical sub-assembly section of the plug body of the plug.

In some embodiments, the present disclosure provides a heatsink fin adapter assembly method including aligning a heatsink fin adapter assembly with a plug body of a plug and press-fitting the heatsink fin adapter assembly onto the plug body of the plug with adapter fins the heatsink fin adapter assembly intertwined with heatsink fins of the plug. In some embodiments, the heatsink fin adapter assembly method also includes securing the heatsink fin adapter assembly to the plug body of the plug using one or more screws or other fasteners. In some embodiments, the heatsink fin adapter assembly method further includes disposing thermal gaskets adjacent to sides of the plug body of the plug and adapter side walls of the heatsink fin adapter assembly. The heatsink fin adapter assembly method still further includes disposing a cold plate or chassis heatsink over the heatsink fin adapter assembly.

It will be readily apparent to those of ordinary skill in the art that aspects and features of each of the described embodiments may be incorporated, omitted, and/or combined as desired in a given application, without limitation.

### BRIEF DESCRIPTION OF THE DRAWINGS

The present disclosure is illustrated and described with reference to the various drawings, in which like reference numbers are used to denote like assembly components/method steps, as appropriate, and in which:

FIG. 1 illustrates a conventional TROSA conduction cooling heatsink assembly;

FIG. 2 illustrates one embodiment of the TROSA conduction cooling heatsink assembly of the present disclosure;

FIG. 3 is a perspective view of the heatsink fin adapter assembly of the TROSA conduction cooling heatsink assembly of FIG. 2;

FIG. 4 is a perspective view of the heatsink fin adapter assembly being press-fit onto the heatsink fins and plug of the TROSA conduction cooling heatsink assembly of FIG. 2;

FIG. 5 is a perspective view of the heatsink fin adapter assembly press-fit onto the heatsink fins and plug of the TROSA conduction cooling heatsink assembly of FIG. 2;

FIG. 6 illustrates another embodiment of the TROSA conduction cooling heatsink assembly of the present disclosure;

FIG. 7 is a perspective view of the heatsink fin adapter assembly of the TROSA conduction cooling heatsink assembly of FIG. 6;

FIG. 8 is a perspective view of the heatsink fin adapter assembly being press-fit onto and secured to the heatsink fins and plug of the TROSA conduction cooling heatsink assembly of FIG. 6;

FIG. 9 is a perspective view of the heatsink fin adapter assembly press-fit onto and secured to the heatsink fins and plug of the TROSA conduction cooling heatsink assembly of FIG. 6; and

FIG. 10 is a flowchart illustrating one embodiment of the heatsink fin adapter assembly method of the present disclosure.

It will be readily apparent to those of ordinary skill in the art that aspects and features of each of the illustrated embodiments may be incorporated, omitted, and/or combined as desired in a given application, without limitation.

### DETAILED DESCRIPTION

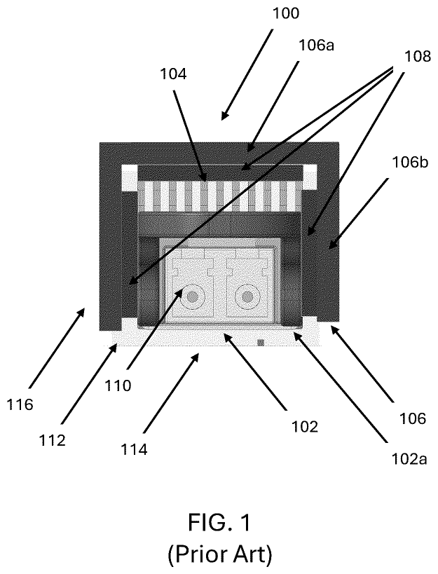

Again, the present disclosure provides a TROSA heatsink fin adapter assembly that replaces at least the top thermal gasket of the arrangement of FIG. 1, and optionally all of the thermal gaskets of the arrangement, to more effectively thermally couple the heatsink fins and plug body of the plug with the cold plate or chassis heatsink. The TROSA heatsink fin adapter assembly includes an adapter body that is disposed above and around the heatsink fins of the plug and a plurality of adapter fins that are disposed between and intertwined with the heatsink fins of the plug. Optionally, the TROSA heatsink fin adapter assembly includes adapter sides that are also disposed adjacent to the sides of the plug body. Thus, the TROSA heatsink fin adapter provides a conformal thermal interface between the heatsink fins and plug body of the plug and the cold plate or chassis heatsink. The result is the TROSA of the high power optics of the BiDi coherent plug of an air cooled conduction system, such as an outdoor system, being adequately cooled, even with total plug powers of ˜19 W and plug section powers of ˜1.5-11 W, for example, under most ambient conditions.

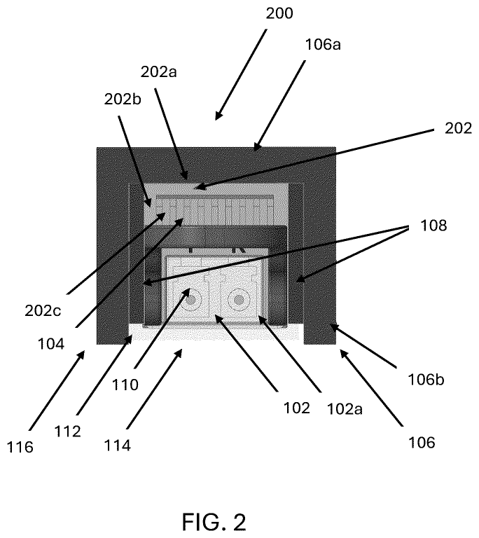

FIG. 2 shows one embodiment of the TROSA conduction cooling heatsink assembly 200 of the present disclosure. As shown, the plug 102, which may be a QSFP-DD or the like, again includes a plurality of heatsink fins 104 that are coupled to or integrally formed with and extend from the plug body 102a of the plug 102. These heatsink fins 104 are normally associated with convection cooling, but are surrounded by a cold plate or chassis heatsink 106 that surrounds the plug body 102a and heatsink fins 104 of the plug 102, serving to conduct heat away from the plug body 102a and heatsink fins 104. Optionally, the cold plate or chassis heatsink 106 may be liquid cooled, but in any case provides an increased surface area for heat conduction.

The cold plate or chassis heatsink chassis 106 is thermally coupled to the heatsink fins 104 at the top of the plug body 102a by the heatsink fin adapter assembly 202 of the present disclosure. The heatsink fin adapter assembly 202 includes an adapter body 202a that is disposed above the heatsink fins 104 of the plug 102 and adapter side walls 202b that are disposed around the heatsink fins 104 of the plug 102. The adapter body 202a may contact the tips of the heatsink fins 104, in the case that the heatsink fin adapter assembly 202 is specifically designed for the type of plug 102, or may be spaced apart from the tips of the heatsink fins 104, in the case that the heatsink fin adapter assembly 202 is merely compatible with the type of plug 102, but not specifically designed for the type of plug 102. The adapter side walls 202b are coextensive and make contact with the outermost heatsink fins 104. The heatsink fin adapter assembly 202 also includes a plurality of adapter fins 202c that are disposed between and intertwined with the heatsink fins 104 of the plug 102. As mentioned above, the spacing of the heatsink fins 104, which are typically manufactured from aluminum or the like, is on the order to 0.8-1 mm, for example. Thus, the thickness of the adapter fins 202c, which are also manufactured from aluminum or the like and are staggered with respect to the heatsink fins 104, is also on the order to 0.8-1 mm, for example. A thermal interface material (TIM) may be applied to all surfaces of the heatsink fin adapter assembly 202, via spraying, dipping, etc., to promote thermal conduction and provide a degree of manufacturing and fit tolerance. Thus, the heatsink fin adapter assembly 202 provides a conformal thermal interface between the heatsink fins 104 of the plug 102 and the cold plate or chassis heatsink 106.

In this embodiment, the cold plate or heatsink chassis 106 is also thermally coupled to the plug body 102a via one or more thermal gaskets 108 disposed between the side heatsink portions 106b of the cold plate or chassis heatsink 106 and the plug body 102a and adapter side walls 202b of the heatsink fin adapter assembly 202. These thermal gaskets 108 may each be manufactured from a compliant thermal transmission material, include a thermally transmissive GoF pad, or the like. It should again be noted that the cold plate or heatsink chassis 106 includes a top heatsink portion 106a disposed along the top of the heatsink fins 104 and heatsink fin adapter assembly 202 and side heatsink portions 106b that extend downwards along the sides of the heatsink fins 104 and heatsink fin adapter assembly 202 and the plug body 102a.

The enhanced contact between the heatsink fins 104 and thermal gaskets 108 and cold plate or chassis heatsink 106 through the heatsink fin adapter assembly 202 enhances thermal conduction, which is advantageous for the TROSA 110 of the high power optics of the BiDi coherent plug 102 of an air cooled conduction system, such as an outdoor system. In such applications, the TROSA 110, which extends from the faceplate or wall 112 of the associated module 114 of the system 116, may consume 10 W, for example, generating excessive heat. The result is conduction cooled systems with total plug powers of ˜19 W and plug section powers of ˜1.5-11 W being adequately cooled under most ambient conditions.

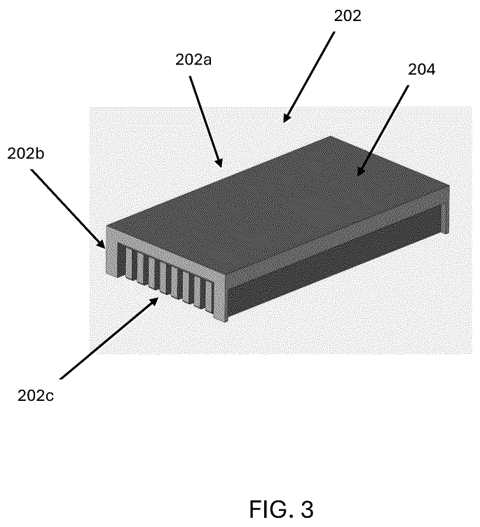

FIG. 3 is a perspective view of the heatsink fin adapter assembly 202 of the TROSA conduction cooling heatsink assembly 200 of FIG. 2. Again, the heatsink fin adapter assembly 202 includes the adapter body 202a, the adapter side walls 202b, and the plurality of adapter fins 202c. The TIM 204 may be applied to all surfaces of the heatsink fin adapter assembly 202, via spraying, dipping, etc., to promote thermal conduction. Thus, the heatsink fin adapter assembly 202 provides a conformal thermal interface between the heatsink fins 104 of the plug 102 and the cold plate or chassis heatsink 106.

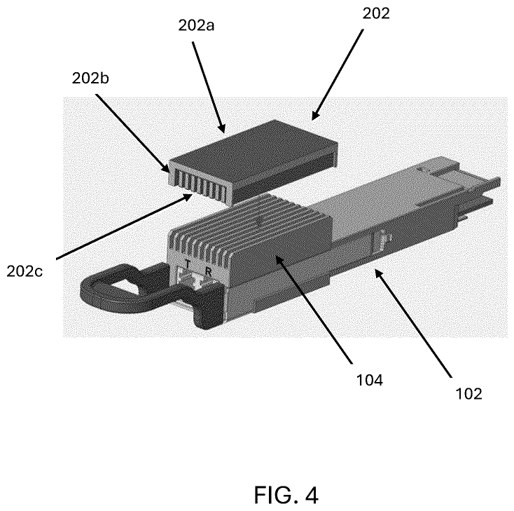

FIG. 4 is a perspective view of the heatsink fin adapter assembly 202 being press-fit onto the heatsink fins 104 and plug 102 of the TROSA conduction cooling heatsink assembly 200 of FIG. 2. Again, the heatsink fin adapter assembly 202 includes the adapter body 202a that is disposed above the heatsink fins 104 of the plug 102 and the adapter side walls 202b that are disposed around the heatsink fins 104 of the plug 102. The adapter side walls 202b are coextensive and make contact with the outermost heatsink fins 104. The heatsink fin adapter assembly 202 also includes the plurality of adapter fins 202c that are disposed between and intertwined with the heatsink fins 104 of the plug 102. As mentioned above, the spacing of the heatsink fins 104, which are typically manufactured from aluminum or the like, is on the order to 0.8-1 mm, for example. Thus, the thickness of the adapter fins 202c, which are also manufactured from aluminum or the like and are staggered with respect to the heatsink fins 104, is also on the order to 0.8-1 mm, for example.

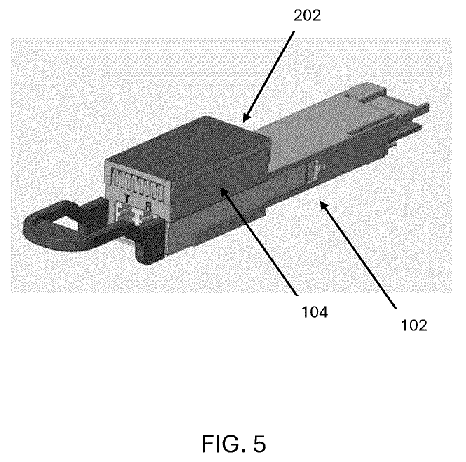

FIG. 5 is a perspective view of the heatsink fin adapter assembly 202 press-fit onto the heatsink fins 104 and plug 102 of the TROSA conduction cooling heatsink assembly 200 of FIG. 2. The TROSA 110, heatsink fins 104, and heatsink fin adapter assembly 202 extend from the faceplate or wall 112 of the associated module 114 of the system 116, such that the cold plate or heatsink chassis 106 can be applied around the heatsink fin adapter assembly 202 to provide enhanced conduction cooling of the plug 102.

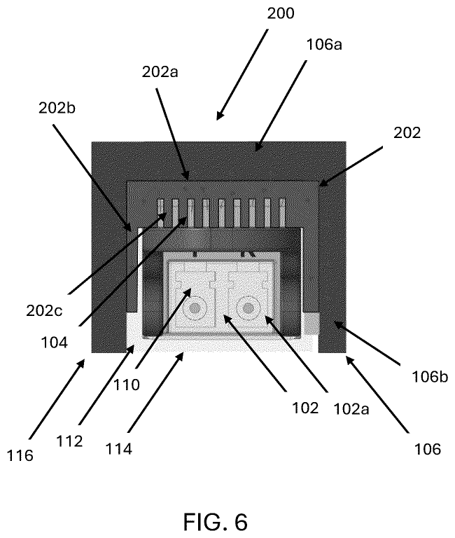

FIG. 6 shows another embodiment of the TROSA conduction cooling heatsink assembly 200 of the present disclosure. As shown, the plug 102, which may be a QSFP-DD or the like, again includes a plurality of heatsink fins 104 that are coupled to or integrally formed with and extend from the plug body 102a of the plug 102. These heatsink fins 104 are normally associated with convection cooling, but are surrounded by a cold plate or chassis heatsink 106 that surrounds the plug body 102a and heatsink fins 104 of the plug 102, serving to conduct heat away from the plug body 102a and heatsink fins 104. Optionally, the cold plate or chassis heatsink 106 may be liquid cooled, but in any case provides an increased surface area for heat conduction.

The cold plate or chassis heatsink chassis 106 is thermally coupled to the heatsink fins 104 at the top of the plug body 102a by the heatsink fin adapter assembly 202 of the present disclosure. The heatsink fin adapter assembly 202 includes an adapter body 202a that is disposed above the heatsink fins 104 of the plug 102 and adapter side walls 202b that are disposed around the heatsink fins 104 of the plug 102 and the sides of the plug body 102a. The adapter body 202a may contact the tips of the heatsink fins 104, in the case that the heatsink fin adapter assembly 202 is specifically designed for the type of plug 102, or may be spaced apart from the tips of the heatsink fins 104, in the case that the heatsink fin adapter assembly 202 is merely compatible with the type of plug 102, but not specifically designed for the type of plug 102. The adapter side walls 202b are coextensive and make contact with the outermost heatsink fins 104 and are disposed adjacent to the sides of the plug body 102a, optionally making contact with the sides of the plug body 102a. The heatsink fin adapter assembly 202 also includes a plurality of adapter fins 202c that are disposed between and intertwined with the heatsink fins 104 of the plug 102. As mentioned above, the spacing of the heatsink fins 104, which are typically manufactured from aluminum or the like, is on the order to 0.8-1 mm, for example. Thus, the thickness of the adapter fins 202c, which are also manufactured from aluminum or the like and are staggered with respect to the heatsink fins 104, is also on the order to 0.8-1 mm, for example. A TIM may be applied to all surfaces of the heatsink fin adapter assembly 202, via spraying, dipping, etc., to promote thermal conduction and provide a degree of manufacturing and fit tolerance. Thus, the heatsink fin adapter assembly 202 provides a conformal thermal interface between the heatsink fins 104 of the plug 102 and the cold plate or chassis heatsink 106.

In this embodiment, the cold plate or heatsink chassis 106 is also thermally coupled to the plug body 102a and heatsink fins 104 via contact between the side heatsink portions 106b of the cold plate or heatsink chassis 106 and the plug body 102a through elongated coextensive adapter side walls 202b of the heatsink fin adapter assembly 202. It should again be noted that the cold plate or heatsink chassis 106 includes a top heatsink portion 106a disposed along the top of the heatsink fins 104 and heatsink fin adapter assembly 202 and side heatsink portions 106b that extend downwards along the sides of the heatsink fins 104 and the plug body 102a along the elongated coextensive heatsink fin adapter assembly 202. In this embodiment, essentially three thermal contact surfaces (top and two sides) are provided between the cold plate or heatsink chassis 106 and the heatsink fin adapter assembly 202, which has three contact surfaces (top and two sides) with the heatsink fins 104 and plug body 102a, due to the intervening presence of the elongated coextensive adapter side walls 202b of the heatsink fin adapter assembly 202.

The enhanced contact between the heatsink fins 104 and plug body 102a and cold plate or chassis heatsink 106 through the heatsink fin adapter assembly 202 enhances thermal conduction, which is advantageous for the TROSA 110 of the high power optics of the BiDi coherent plug 102 of an air cooled conduction system, such as an outdoor system. In such applications, the TROSA 110, which extends from the faceplate or wall 112 of the associated module 114 of the system 116, may consume 10 W, for example, generating excessive heat. The result is conduction cooled systems with total plug powers of ˜19 W and plug section powers of ˜1.5-11 W being adequately cooled under most ambient conditions. FIG. 6 shows the heat conduction from the TROSA 110 of the plug 102 and through the heatsink fins 104, heatsink fin adapter assembly 202, and cold plate or heatsink chassis 106.

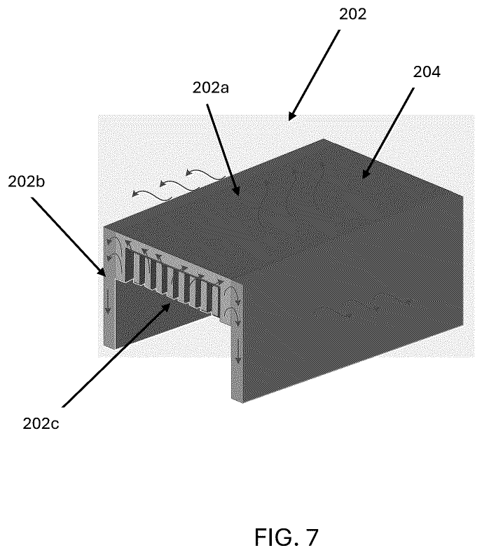

FIG. 7 is a perspective view of the heatsink fin adapter assembly 202 of the TROSA conduction cooling heatsink assembly 200 of FIG. 6. Again, the heatsink fin adapter assembly 202 includes the adapter body 202a, the elongated adapter side walls 202b, and the plurality of adapter fins 202c. The TIM 204 may be applied to all surfaces of the heatsink fin adapter assembly 202, via spraying, dipping, etc., to promote thermal conduction. Thus, the heatsink fin adapter assembly 202 provides a conformal thermal interface between the heatsink fins 104 and plug body 102a of the plug 102 and the cold plate or chassis heatsink 106. FIG. 7 shows the heat conduction through the heatsink fin adapter assembly 202.

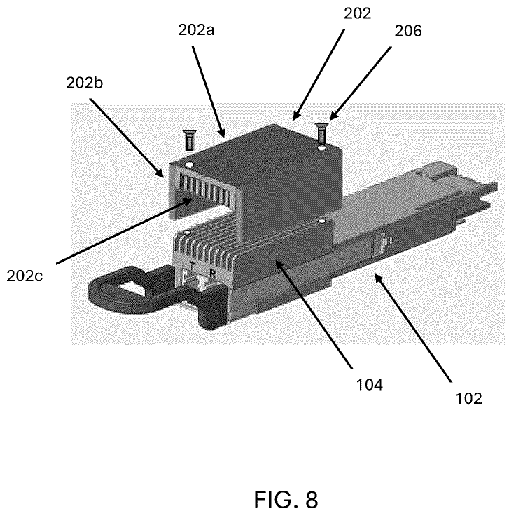

FIG. 8 is a perspective view of the heatsink fin adapter assembly 202 being press-fit onto and secured to the heatsink fins 104 and plug 102 of the TROSA conduction cooling heatsink assembly 200 of FIG. 6. Again, the heatsink fin adapter assembly 202 includes the adapter body 202a that is disposed above the heatsink fins 104 of the plug 102 and the adapter side walls 202b that are disposed around the heatsink fins 104 of the plug 102 and the sides of the plug body 102a. The adapter side walls 202b are coextensive and make contact with the outermost heatsink fins 104, as well as the sides of the plug body 102a. The heatsink fin adapter assembly 202 also includes the plurality of adapter fins 202c that are disposed between and intertwined with the heatsink fins 104 of the plug 102. As mentioned above, the spacing of the heatsink fins 104, which are typically manufactured from aluminum or the like, is on the order to 0.8-1 mm, for example. Thus, the thickness of the adapter fins 202c, which are also manufactured from aluminum or the like and are staggered with respect to the heatsink fins 104, is also on the order to 0.8-1 mm, for example. Securement of the heatsink fin adapter assembly 202 to the heatsink fins 104 and plug 102 is accomplished via one or more screws or other fasteners 206 once the heatsink fin adapter assembly 202 is press-fit onto the heatsink fins 104 and around the plug body 102a.

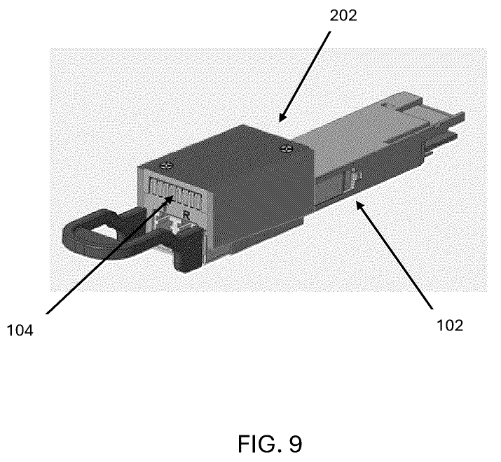

FIG. 9 is a perspective view of the heatsink fin adapter assembly 202 press-fit onto and secured to the heatsink fins 104 and plug 102 of the TROSA conduction cooling heatsink assembly 200 of FIG. 6. The TROSA 110, heatsink fins 104, and heatsink fin adapter assembly 202 extend from the faceplate or wall 112 of the associated module 114 of the system 116, such that the cold plate or heatsink chassis 106 can be applied around the heatsink fin adapter assembly 202 to provide enhanced conduction cooling of the plug 102.

Advantageously, in all embodiments, the heatsink fin adapter assembly 202 of the present disclosure allows the cold plate or heatsink chassis 106 to be used with a plug 102 with heatsink fins 104 of any height within a given range, the intertwined fin mechanism accommodating a range of heatsink fin heights. The adapter side walls 202b of the heatsink fin adapter assembly 202 may be shorter, corresponding only to the height of the heatsink fins 104, or it may be longer, corresponding to the height of the heatsink fins 104 and the plug body 102a. Thermal gaskets 108 may be disposed between the side heatsink portions 106b of the cold plate or chassis heatsink 106 and the plug body 102a and adapter side walls 202b of the heatsink fin adapter assembly 202, or may be omitted when longer adapter side walls 202b are utilized.

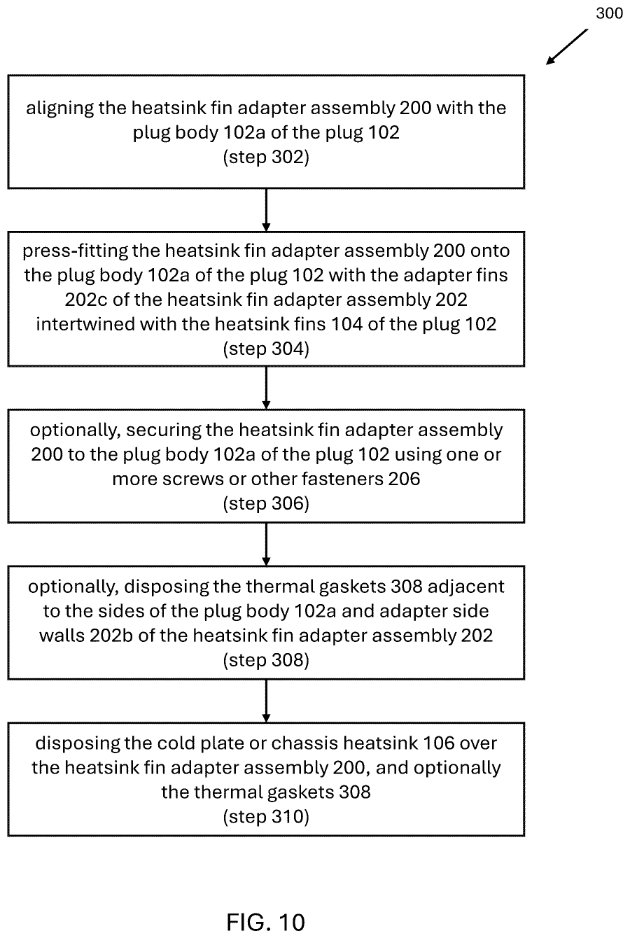

FIG. 10 is a flowchart illustrating one embodiment of the heatsink fin adapter assembly method 300 of the present disclosure. The heatsink fin adapter assembly method 300 first includes aligning the heatsink fin adapter assembly 200 with the plug body 102a of the plug 102 (step 302). The heatsink fin adapter assembly method 300 second includes press-fitting the heatsink fin adapter assembly 200 onto the plug body 102a of the plug 102 with the adapter fins 202c of the heatsink fin adapter assembly 202 intertwined with the heatsink fins 104 of the plug 102 (step 304). Optionally, the heatsink fin adapter assembly method 300 third includes securing the heatsink fin adapter assembly 200 to the plug body 102a of the plug 102 using one or more screws or other fasteners 206 (step 306). Optionally, the heatsink fin adapter assembly method 300 fourth includes disposing the thermal gaskets 308 adjacent to the sides of the plug body 102a and adapter side walls 202b of the heatsink fin adapter assembly 202 (step 308). The heatsink fin adapter assembly method 300 fifth includes disposing the cold plate or chassis heatsink 106 over the heatsink fin adapter assembly 200, and optionally the thermal gaskets 308 (step 310).

Although the present disclosure is illustrated and described with reference to specific embodiments and examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. A heatsink fin adapter assembly comprising
an adapter body adapted to be disposed above a plurality of heatsink fins of a plug,
adapter side walls adapted to be disposed around the plurality of heatsink fins of the plug, and
a plurality of adapter fins extending from the adapter body between the adapter side walls adapted to be disposed between and intertwined with the plurality of heatsink fins of the plug,
wherein the adapter body, the adapter side walls, and the plurality of adapter fins are adapted to conduct heat from the plurality of heatsink fins and a plug body of the plug.

2. The heatsink fin adapter assembly of claim 1, wherein the adapter body is adapted to be disposed adjacent to tips of the plurality of heatsink fins of the plug.

3. The heatsink fin adapter assembly of claim 1, wherein the adapter body is adapted to be spaced apart from tips of the plurality of heatsink fins of the plug.

4. The heatsink fin adapter assembly of claim 1, wherein the adapter body is adapted to be disposed adjacent to a top heatsink portion of a cold plate or chassis heatsink disposed about the heatsink fin adapter assembly.

5. The heatsink fin adapter assembly of claim 1, wherein the adapter side walls are elongated such that the adapter side walls are adapted to be disposed adjacent to sides of the plug body of the plug.

6. The heatsink fin adapter assembly of claim 1, wherein the adapter side walls are adapted to be disposed adjacent to heatsink side portions of a cold plate or chassis heatsink disposed about the heatsink fin adapter assembly.

7. The heatsink fin adapter assembly of claim 6, wherein the adapter side walls are adapted to be disposed adjacent to the heatsink side portions of the cold plate or chassis heatsink disposed about the heatsink fin adapter assembly through intervening thermal gaskets.

8. The heatsink fin adapter assembly of claim 1, wherein surfaces of one or more of the adapter body, the adapter side walls, and the plurality of adapter fins are coated with a thermal interface material.

9. The heatsink fin adapter assembly of claim 1, wherein the plurality of heatsink fins are disposed adjacent to a transmit-receive optical sub-assembly section of the plug body of the plug.

10. The heatsink fin adapter assembly of claim 1, wherein the plug is a bidirectional coherent optics plug.

11. A transmit-receive optical sub-assembly conduction cooling heatsink assembly comprising
a heatsink fin adapter assembly comprising
an adapter body adapted to be disposed above a plurality of heatsink fins of a plug,
adapter side walls adapted to be disposed around the plurality of heatsink fins of the plug, and
a plurality of adapter fins extending from the adapter body between the adapter side walls adapted to be disposed between and intertwined with the plurality of heatsink fins of the plug, and
a cold plate or chassis heatsink disposed about the heatsink fin adapter assembly,
wherein the adapter body, the adapter side walls, and the plurality of adapter fins of the heatsink fin adapter assembly are adapted to conduct heat from the plurality of heatsink fins and a plug body of the plug to the cold plate or chassis heatsink.

12. The transmit-receive optical sub-assembly conduction cooling heatsink assembly of claim 11, wherein the adapter body is adapted to be disposed adjacent to tips of the plurality of heatsink fins of the plug.

13. The transmit-receive optical sub-assembly conduction cooling heatsink assembly of claim 11, wherein the adapter body is adapted to be spaced apart from tips of the plurality of heatsink fins of the plug.

14. The transmit-receive optical sub-assembly conduction cooling heatsink assembly of claim 11, wherein the adapter body is adapted to be disposed adjacent to a top heatsink portion of the cold plate or chassis heatsink disposed about the heatsink fin adapter assembly.

15. The transmit-receive optical sub-assembly conduction cooling heatsink assembly of claim 11, wherein the adapter side walls are elongated such that the adapter side walls are adapted to be disposed adjacent to sides of the plug body of the plug.

16. The transmit-receive optical sub-assembly conduction cooling heatsink assembly of claim 11, wherein the adapter side walls are adapted to be disposed adjacent to heatsink side portions of the cold plate or chassis heatsink disposed about the heatsink fin adapter assembly.

17. The transmit-receive optical sub-assembly conduction cooling heatsink assembly of claim 16, wherein the adapter side walls are adapted to be disposed adjacent to the heatsink side portions of the cold plate or chassis heatsink disposed about the heatsink fin adapter assembly through intervening thermal gaskets.

18. The transmit-receive optical sub-assembly conduction cooling heatsink assembly of claim 11, wherein surfaces of one or more of the adapter body, the adapter side walls, and the plurality of adapter fins are coated with a thermal interface material.

19. The transmit-receive optical sub-assembly conduction cooling heatsink assembly of claim 11, wherein the plurality of heatsink fins are disposed adjacent to a transmit-receive optical sub-assembly section of the plug body of the plug.

20. A heatsink fin adapter assembly method comprising
aligning a heatsink fin adapter assembly with a plug body of a plug, and
press-fitting the heatsink fin adapter assembly onto the plug body of the plug with adapter fins of the heatsink fin adapter assembly intertwined with heatsink fins of the plug.
